(19) United States
(12) Patent Application Publication
(10) Pub. No.: US 2023/0136640 A1
(43) Pub. Date: May 4, 2023

(54) POLISHING SLURRY COMPOSITION

(71) Applicant: KCTECH CO., LTD., Gyeonggi-do (KR)

(72) Inventors: Chang Gil KWON, Gyeonggi-do (KR); Sung Pyo LEE, Gyeonggi-do (KR)

(73) Assignee: KCTECH CO., LTD., Gyeonggi-do (KR)

(21) Appl. No.: 17/977,702

(22) Filed: Oct. 31, 2022

(30) Foreign Application Priority Data
Nov. 1, 2021 (KR) 10-2021-0148153

(51) Int. Cl. C09G 1/02; H01L 21/306

(52) U.S. Cl. CPC C09G 1/02; H01L 21/30625

(57) ABSTRACT

Provided is a polishing slurry composition including abrasive particles, a dispersant, a pH buffering agent, and a dishing inhibitor including at least one selected from a group consisting of a saccharides compound, an amino acid, and a mixture thereof.

### CROSS-REFERENCE TO RELATED APPLICATION

This application claims the benefit of Korean Patent Application No. 10-2021-0148153 filed on Nov. 1, 2021, in the Korean Intellectual Property Office, the entire disclosure of which is incorporated herein by reference for all purposes.

### BACKGROUND

### 1. Field of the Invention

One or more example embodiments relate to a polishing slurry composition, and more particularly, to a polishing slurry composition capable of minimizing the amount of dishing occurred on a low stepped portion of a patterned wafer having a wide width.

### 2. Description of the Related Art

A chemical mechanical polishing (CMP) process is performed by putting a slurry containing an abrasive particle on a substrate and using a polishing pad mounted on a polishing apparatus. Here, the abrasive particle is subjected to pressure from the polishing apparatus to mechanically polish a surface, and a chemical component included in the slurry composition chemically reacts to the surface of the substrate to chemically remove the surface portion of the substrate.

The CMP process is used for a planarization process of an interlayer insulating film, a shallow trench isolation (STI) process, formation of a plug and buried metal wiring in a semiconductor device manufacturing process.

An STI process introduces a technology for etching an isolation portion, forming a trench, depositing an oxide, and then performing planarization through CMP. Here, a selective polishing characteristic of increasing a polishing rate of an oxide layer that is an insulating film and reducing a polishing rate of a nitride layer that is a diffusion barrier is required.

However, an increased selective polishing characteristic, that is, a high selectivity of an oxide film to a nitride film, may cause dishing on the oxide film and this may induce problems regarding reliability and current leakage due to electron tunneling in a completed semiconductor chip.

Therefore, slurry compositions for reducing the oxide film dishing while increasing the polishing selectivity of the oxide film to the nitride film have been studied, but in case of a slurry composition of the related art, the performance is implemented only for a low stepped portion of a patterned wafer having a width of 500 micrometers (μm) or less, and a dishing reduction performance for a low stepped portion of the patterned wafer having a wider width than the above width is not implemented.

Accordingly, there has been a demand for development of a polishing slurry composition capable of minimizing the oxide film dishing on a low stepped portion of a patterned wafer having a wide width while increasing the polishing selectivity of the oxide film to the nitride film.

The above description has been possessed or acquired by the inventor(s) in the course of conceiving the present disclosure and is not necessarily an art publicly known before the present application is filed.

### SUMMARY

The present disclosure is to solve the above problems, and an object of the present disclosure is to provide a polishing slurry composition capable of minimizing oxide film dishing on a low stepped portion of a patterned wafer having a wide width while increasing a polishing selectivity of an oxide film to a nitride film.

However, aspects of the present disclosure are not limited to the one set forth herein, and other aspects not mentioned herein would be clearly understood by one of ordinary skill in the art from the following description.

According to an aspect, there is provided a polishing slurry composition including abrasive particles; a dispersant; a pH buffering agent; and a dishing inhibitor including at least one selected from a group consisting of a saccharides compound, an amino acid, and a mixture thereof. According to an example embodiment, the abrasive particles may include at least one selected from a group consisting of: a metal oxide; a metal oxide coated with an organic material or inorganic material; and the metal oxide in a colloidal phase, and the metal oxide may include at least one selected from a group consisting of silica, ceria, zirconia, alumina, titania, barium titania, germania, mangania, and magnesia.

According to an example embodiment, a primary particle size of the abrasive particles may be 5 nanometers (nm) to 150 nm, and a secondary particle size of the abrasive particles may be 30 nm to 300 nm.

According to an example embodiment, the abrasive particles may be dispersed so that surfaces of the abrasive particles have positive charges.

According to an example embodiment, the abrasive particles may be in an amount of 0.1 wt % to 10 wt %.

According to an example embodiment, the dispersant may include at least one selected from a group consisting of picolinic acid, dipicolinic acid, benzoic acid, phenylacetic acid, naphthoic acid, mandelic acid, nicotinic acid, dinicotinic acid, isonicotinic acid, quinolinic acid, anthranilic acid, fusaric acid, phthalic acid, isophthalic acid, terephthalic acid, toluic acid, salicylic acid, nitrobenzoic acid, and pyridinedicarboxylic acid.

According to an example embodiment, the dispersant may be in an amount of 0.1 wt % to 10 wt %.

According to an example embodiment, the pH buffering agent may include an amino acid, and the amino acid may include at least one selected from a group consisting of histidine, lysine, and arginine.

According to an example embodiment, the pH buffering agent may be in an amount of 0.01 wt % to 5 wt %.

According to an example embodiment, the saccharides compound may include at least one selected from a group consisting of monosaccharides, polysaccharides, sugar alcohol, and a salt thereof.

According to an example embodiment, the saccharides compound may include four or more hydroxy groups (—OH).

According to an example embodiment, the saccharides compound may include a hydroxy group and an amine group.

According to an example embodiment, the dishing inhibitor may include at least one selected from a group consisting of proline, ribose, glucose, sorbitol, N-acetyl-D-glucosamine, and glucosamine hydrochloride.

According to an example embodiment, the dishing inhibitor may be in an amount of 0.001 wt % to 1 wt %.

According to an example embodiment, the polishing slurry composition may further include a pH adjuster, The pH adjuster may include at least one selected from a group consisting of lactic acid, pimelic acid, malic acid, malonic acid, maleic acid, acetic acid, adipic acid, oxalic acid, succinic acid, tartaric acid, citric acid, glutaric acid, glycolic acid, formic acid, fumaric acid, propionic acid, butyric acid, hydroxybutyric acid, aspartic acid, itaconic acid, tricarballylic acid, suberic acid, sebacic acid, stearic acid, pyruvic acid, acetoacetic acid, glyoxylic acid, azelaic acid, a caprylic acid, lauric acid, myristic acid, valeric acid, and palmitic acid.

According to an example embodiment, the polishing slurry composition may be a positive slurry composition showing a positive charge.

According to an example embodiment, the pH of the polishing slurry composition may range from 4 to 6.

According to an example embodiment, the polishing slurry composition may be configured to polish a patterned wafer having a width of 2,000 micrometers (μm) or more, and the amount of dishing occurred on a low stepped portion of the patterned wafer may be 1,600 angstroms (Å) or less.

According to an example embodiment, a polishing speed of an oxide film (SiO₂) may be 2,000 Å/min or more, and a polishing selectivity of the oxide film (SiO₂) to a nitride film (SiN) (the polishing speed of the oxide film (SiO₂)/a polishing speed of the nitride film (SiN)) may be 200 or more.

Additional aspects of example embodiments will be set forth in part in the description which follows and, in part, will be apparent from the description, or may be learned by practice of the disclosure.

According to example embodiments, the polishing slurry composition is effective in having a high polishing selectivity of an oxide film to a nitride film and minimizing oxide film dishing on a low stepped portion of a patterned wafer having a wide.

### DETAILED DESCRIPTION

Hereinafter, example embodiments will be described in detail with reference to the accompanying drawings. However, various alterations and modifications may be made to the example embodiments. Here, the example embodiments are not construed as limited to the disclosure. The example embodiments should be understood to include all changes, equivalents, and replacements within the idea and the technical scope of the disclosure.

The terminology used herein is for the purpose of describing particular example embodiments only and is not to be limiting of the example embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the example embodiments with reference to the accompanying drawings, like reference numerals refer to like components and a repeated description related thereto will be omitted. In the description of example embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the example embodiments. These terms are used only for the purpose of discriminating one component from another component, and the nature, the sequences, or the orders of the components are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

The same name may be used to describe an element included in the example embodiments described above and an element having a common function. Unless otherwise mentioned, the descriptions on the example embodiments may be applicable to the following example embodiments and thus, duplicated descriptions will be omitted for conciseness.

An aspect of the present disclosure provides a polishing slurry composition including: abrasive particles; a dispersant; a pH buffering agent; and a dishing inhibitor including at least one selected from a group consisting of a saccharides compound, an amino acid, and a mixture thereof.

The polishing slurry composition according to the present disclosure may include the dishing inhibitor to exhibit an effect of increasing a polishing selectivity of an oxide film to a nitride film and minimizing oxide film dishing on a low stepped portion of a patterned wafer having a wide width (space).

The low stepped portion of the patterned wafer refers to a recessed portion of a step.

According to an example embodiment, the abrasive particles may include: at least one selected from a group consisting of a metal oxide; a metal oxide coated with an organic material or inorganic material; and the metal oxide in a colloidal phase, and the metal oxide may include at least one selected from a group consisting of silica, ceria, zirconia, alumina, titania, barium titania, germania, mangania, and magnesia. For example, the abrasive particles may be colloidal ceria.

The abrasive particles may provide high dispersion stability and accelerate oxidation of an inorganic oxide film, which is a film to be polished, to easily polish the inorganic oxide film, thereby achieving a high polishing property while minimizing defects such as scratches or the like.

According to an example embodiment, the abrasive particles may include, for example, abrasive particles prepared by a liquid-phase method. The liquid-phase method may include, for example, a sol-gel method of subjecting an abrasive particle precursor to a chemical reaction in an aqueous solution and growing crystals to obtain fine particles, a coprecipitation method of precipitating abrasive particle ions in an aqueous solution, and a hydrothermal synthesis method of forming abrasive particles under a high temperature and a high pressure to prepare the abrasive particles.

According to an example embodiment, the abrasive particles may be dispersed so that surfaces of the abrasive particles have positive charges. The abrasive particles may be prepared by the liquid-phase method, and in this case, the abrasive particles may be dispersed so that the surfaces of the abrasive particles have positive charges.

The abrasive particles may include monocrystalline particles. When monocrystalline abrasive particles are used, a scratch reduction effect may be achieved in comparison to polycrystalline abrasive particles, and dishing may be improved.

A shape of the abrasive particles may include, for example, at least one of a spherical shape, a square shape, a needle shape, or a plate shape, and may desirably be the spherical shape.

The abrasive particles may include mixed particles having a multi-dispersion type particle distribution in addition to single-sized particles. For example, abrasive particles with two different types of average particle sizes may be mixed to have a bimodal particle distribution, or abrasive particles with three different types of average particle sizes may be mixed to have a particle size distribution showing three peaks. Also, abrasive particles with at least four different types of average particle sizes may be mixed to have a multi-dispersion type particle distribution. Relatively large abrasive particles and relatively small abrasive particles may be mixed, to have a better dispersibility, and an effect of reducing scratches on a wafer surface may be expected.

According to an example embodiment, the abrasive particles may include primary particles, secondary particles, or both.

According to an example embodiment, a primary particle size of the abrasive particles may be 5 nanometers (nm) to 150 nm and a secondary particle size of the abrasive particles may be 30 nm to 300 nm.

A size of the abrasive particle may refer to an average value of particle sizes of a plurality of particles within a field of view which may be measured by a scanning electron microscope analysis or dynamic light scattering.

When the primary particle size of the abrasive particles is less than the above range, a problem regarding a significant decrease in a polishing speed may occur, and when the primary particle size exceeds the above range, a problem regarding an increase in a probability of occurrence of scratches may occur.

When the secondary particle size of the abrasive particles is less than the above range, a polishing rate may be reduced, and when the secondary particle size exceeds the above range, it may be difficult to control the selectivity due to excessive polishing, which may cause an increase in the amount of the oxide film dishing.

According to an example embodiment, the abrasive particles may be in an amount of 0.1 wt % to 10 wt %.

The abrasive particles may be desirably in an amount of 0.5 wt % to 5 wt % and more desirably in an amount of 0.5 wt % to 1 wt %.

When the amount of the abrasive particles is less than the above range, the polishing rate may be reduced, and when the amount thereof exceeds the above range, defects such as scratches due to the excessive polishing may occur, and surface defects may occur due to adsorption of particles remaining on a surface as the number of abrasive particles increases.

According to an example embodiment, the dispersant may include at least one selected from a group consisting of picolinic acid, dipicolinic acid, benzoic acid, phenylacetic acid, naphthoic acid, mandelic acid, nicotinic acid, dinicotinic acid, isonicotinic acid, quinolinic acid, anthranilic acid, fusaric acid, phthalic acid, isophthalic acid, terephthalic acid, toluic acid, salicylic acid, nitrobenzoic acid, and pyridinedicarboxylic acid.

According to an example embodiment, the dispersant may be in an amount of 0.1 wt % to 10 wt %.

The dispersant may be desirably in an amount of 0.1 wt % to 5 wt % and more desirably in an amount of 0.5 wt % to 1 wt %.

When the content of the dispersant is less than the above range, the abrasive particles may not be dispersed which may cause a deterioration in the polishing performance, and it may be difficult to achieve desired polishing selectivity.

On the other hand, when the amount of the dispersant exceeds the above range, the dispersion stability may be deteriorated due to aggregation, which may cause defects on a film to be polished, and a problem regarding a significant decrease in the polishing rate may occur.

According to an example embodiment, the pH buffering agent may include an amino acid, and the amino acid may include at least one selected from a group consisting of histidine, lysine, and arginine.

The pH buffering agent may perform a function of securing dispersibility and dispersion stability of the abrasive particles and may prevent a decrease in the dispersion stability due to additives.

The amino acid has advantages of being able to maintain the polishing rate and serving as a sufficient pH buffer even in a small amount.

According to an example embodiment, the pH buffering agent may be in an amount of 0.01 wt % to 5 wt %.

The pH buffering agent may be desirably in an amount of 0.01 wt % to 1 wt % and more desirably in an amount of 0.1 wt % to 0.3 wt %.

When the amount of the pH buffering agent is less than the above range, the dispersion stability is decreased, which may make it difficult to achieve the desired polishing performance, and a problem regarding a decrease in the polishing speed may occur.

On the other hand, when the amount of the pH buffering agent exceeds the above range, the dispersion stability is decreased and micro-defects or scratches may occur on the film to be polished, due to aggregation of an excessive amount of pH buffering agents, and a problem regarding a decrease in the polishing speed may occur.

The polishing slurry composition includes the dishing inhibitor including at least one selected from the group consisting of a saccharides compound, an amino acid, and a mixture thereof.

According to an example embodiment, the amino acid may include at least one selected from a group consisting of proline, glycine, alanine, methionine, valine, isoleucine, and leucine.

The dishing inhibitor may include a compound including a hydroxyl functional group (—OH) and functions to inhibit the dishing on the oxide film.

That is, the dishing inhibitor may inhibit the dishing on the oxide film while securing high polishing selectivity of an oxide film to a nitride film, at the time of simultaneous polishing of the polishing slurry composition on the nitride film and the oxide film.

According to an example embodiment, the saccharides compound may include at least one selected from a group consisting of monosaccharides, polysaccharides, sugar alcohol, and a salt thereof.

The monosaccharides include both monosaccharides and monosaccharide derivatives.

According to an example embodiment, the monosaccharides may include at least one selected from a group consisting of glucose, ribose, arabinose, lyxose, maltose, allose, altrose, gulose, xylulose, talose, malose, ribulose, idos, lactose, xylose, galactose, fructose, and a derivative thereof.

For example, as the monosaccharide derivative, N-acetyl-D-glucosamine may be used.

The polysaccharides include both polysaccharides and polysaccharide derivatives.

According to an example embodiment, the polysaccharides may include at least one selected from a group consisting of gellanum, rhamsan gum, welangum, xanthangum, guargum, karayagum, arabicgum, Locust beangum, tragacanth gum, gum ghatti, tara gum, konjac gum, algin, agar, carrageenan, furcellaran, curdlan, alginic acid, casein, tatagum, tamarind gum, pectin, glucomannan, arabino galactan, pullulian, and acacia gum.

According to an example embodiment, the sugar alcohol may include at least one selected from a group consisting of maltitol, lactitol, threitol, erythritol, ribitol, xylitol, arabitol, adonitol, sorbitol, talitol, isomalt, mannitol, iditol, allodulcitol, dulcitol, sedoheptitol, and perseitol.

The salt of the monosaccharides, polysaccharides and sugar alcohol may refer to a salt of the monosaccharides, a salt of the polysaccharides, and a salt of the sugar alcohol. For example, glucosamine hydrochloride may be used as the salt of the monosaccharides.

According to an example embodiment, the saccharides compound may include four or more hydroxy groups (—OH).

When the saccharides compound includes four or more hydroxy groups, the dishing on the oxide film may be minimized on the low stepped portion of the patterned wafer having a wide width while achieving a high polishing selectivity of the oxide film to the nitride film.

According to an example embodiment, the saccharides compound may include 6 or more hydroxy groups (—OH), and in this case, the polishing selectivity of the oxide film to the nitride film may be maximized.

According to an example embodiment, the saccharides compound may include a hydroxy group and an amine group.

In case of a compound including both the hydroxy group and the amine group, the dishing on the oxide film may be minimized on the low stepped portion of the patterned wafer having a wide width while achieving the maximum polishing selectivity of the oxide film to the nitride film.

According to an example embodiment, the dishing inhibitor may include at least one selected from a group consisting of proline, ribose, glucose, sorbitol, N-acetyl-D-glucosamine, and glucosamine hydrochloride.

According to an example embodiment, the dishing inhibitor may be in an amount of 0.001 wt % to 1 wt %.

The dishing inhibitor may be desirably in an amount of 0.01 wt % to 0.8 wt %, more desirably in an amount of 0.08 wt % to 0.5 wt %, and even more desirably in an amount of 0.08 wt % to 0.3 wt %.

When the amount of the dishing inhibitor is less than the above range, the dishing suppression performance on the oxide film may be deteriorated, and the polishing selectivity of the oxide film to the nitride film may be reduced.

On the other hand, when the amount of the dishing inhibitor exceeds the above range, a problem regarding a significant decrease in the polishing rate may occur.

According to an example embodiment, the polishing slurry composition may further include a pH adjuster, and the pH adjuster may include at least one selected from a group consisting of lactic acid, pimelic acid, malic acid, malonic acid, maleic acid, acetic acid, adipic acid, oxalic acid, succinic acid, tartaric acid, citric acid, glutaric acid, glycolic acid, formic acid, fumaric acid, propionic acid, butyric acid, hydroxybutyric acid, aspartic acid, itaconic acid, tricarballylic acid, suberic acid, sebacic acid, stearic acid, pyruvic acid, acetoacetic acid, glyoxylic acid, azelaic acid, a caprylic acid, lauric acid, myristic acid, valeric acid, and palmitic acid.

The pH adjuster may be added to adjust pH of the polishing slurry composition.

According to an example embodiment, the polishing slurry composition may be used after being concentrated or diluted. In addition, the polishing slurry composition may further include a solvent.

According to an example embodiment, the polishing slurry composition may be a positive slurry composition showing a positive charge.

The polishing slurry composition may have a positive zeta-potential of +10 millivolts (mV) to +60 mV.

The positively charged abrasive particles may maintain a high dispersion stability so that the abrasive particles may not aggregate, thereby reducing an occurrence of micro-scratches.

According to an example embodiment, the pH of the polishing slurry composition may range from 4 to 6. The pH thereof may range desirably from 4 to 5.

When the pH is out of the above range, the dispersibility may decrease to induce aggregation of the particles, thereby causing a problem of inducing scratches or defects.

According to an example embodiment, the polishing slurry composition may be configured to polish a patterned wafer having a width of 2,000 micrometers (μm) or more, and the amount of dishing occurred on a low stepped portion of the patterned wafer may be 1,600 angstroms (Å) or less.

Herein, the low stepped portion may refer to a recessed portion of a step.

In addition, the amount of dishing occurred may refer to a height difference between a projection portion and the recessed portion of the step.

According to an example embodiment, the polishing slurry composition may be configured to polish the patterned wafer having a width of 2,700 μm or more.

According to an example embodiment, the amount of dishing occurred on the low stepped portion of the patterned wafer may be 1,000 Å or less.

The polishing slurry composition according to the present disclosure exhibits an effect of minimizing the oxide film dishing on the low stepped portion of the patterned wafer having the wide width.

That is, the minimizing of amount of the oxide film dishing occurred may prevent defects and improve performance and reliability of a semiconductor device.

According to an example embodiment, in the polishing slurry composition, a polishing speed of an oxide film (SiO₂) may be 2,000 Å/min or more, and a polishing selectivity of the oxide film (SiO₂) to a nitride film (SiN) (the polishing speed of the oxide film (SiO₂)/a polishing speed of the nitride film (SiN)) may be 200 or more.

The polishing slurry composition according to the present disclosure has a characteristic that the polishing selectivity of the oxide film to the nitride film is high.

Particularly, there is an advantage in that a high selectivity of the oxide film may be achieved even at a high oxide film polishing speed of 2,000 Å/min or more.

According to an example embodiment, the polishing slurry composition may be applied to the polishing of a thin film including at least one of an insulating film or an inorganic oxide film.

The insulating film may include at least one selected from a group consisting of a silicon oxide film, a silicon nitride film, and a polysilicon film.

The inorganic oxide film may include at least one selected from a group consisting of fluorine doped tin oxide (FTO, SnO2: F), indium tin oxide (ITO), indium zinc oxide (IZO), indium gallium zinc oxide (IGZO), Al-doped ZnO (AZO), aluminum gallium zinc oxide (AGZO), Ga-doped ZnO (GZO), indium zinc tin oxide (IZTO), indium aluminum zinc oxide (IAZO), indium gallium tin oxide (IGTO), antimony tin oxide (ATO), gallium zinc oxide (GZO), IZO nitride (IZON), SnO₂, ZnO, IrOx, RuOx, and NiO.

According to an example embodiment, the polishing slurry composition may be applied to a polishing process of a semiconductor device, a display device, or both.

According to an example embodiment, the polishing slurry composition may be applied to a shallow trench isolation (STI) process.

Hereinafter, the present disclosure will be described in detail based on examples and comparative examples.

However, the following examples are only for illustrating the present invention, and the present disclosure is not limited to the following examples.

### Example 1

An abrasive particle dispersion was prepared by mixing 4 wt % of colloidal ceria as the abrasive particles and 0.5 wt % of picolinic acid as the dispersant.

0.1 wt % of histidine as the pH buffering agent and 0.1 wt % of proline as the dishing inhibitor were added to the abrasive particle dispersion, and a polishing slurry composition having a pH of 4.5 was prepared using the pH adjuster.

### Example 2

A polishing slurry composition was prepared in the same manner as in Example 1 except that ribose was used as the dishing inhibitor.

### Example 3

A polishing slurry composition was prepared in the same manner as in Example 1 except that glucose was used as the dishing inhibitor.

### Example 4

A polishing slurry composition was prepared in the same manner as in Example 1 except that sorbitol was used as the dishing inhibitor.

### Example 5

A polishing slurry composition was prepared in the same manner as in Example 1 except that N-acetyl-D-glucosamine was used as the dishing inhibitor.

### Example 6

A polishing slurry composition was prepared in the same manner as in Example 1 except that glucosamine hydrochloride was used as the dishing inhibitor.

### Comparative Example 1

A slurry composition was prepared in the same manner as in Example 1 except that the dishing inhibitor was not added.

### Experimental Example

A chemical mechanical polishing (CMP) process was performed using the polishing slurry compositions prepared in the examples and the comparative example under the polishing conditions as described below.

Polishing Conditions

1. Polishing equipment: AP-300 (CTS)

2. Wafer: 300 mm PE-TEOS, LP-SiN, patterned wafer for STI

3. Carrier pressure: 4 psi

4. Spindle speed: 87 rpm

5. Platen speed: 93 rpm

6. Flow rate: 250 mL/min

7. Polishing time: 60 s

Table 1 shows the types of the dishing inhibitor used in each polishing slurry composition and measurement results of the polishing speed (removal rate (RR)) of the oxide film and the nitride film, the polishing selectivity, a degree of occurrence of the oxide film dishing, and a degree of loss of the nitride film.

TABLE 1

| | | | | | | | Patterned wafer (PTW) | |
|---|---|---|---|---|---|---|---|---|
| | | | | Non-patterned wafer (NPW) | | | 2700 um | |
| | | Number of | Number of | SiO2 R/R | SiN R/R | | Dishing | SiN Loss |
| | Dishing inhibitor | hydroxy groups | amine groups | (Å/min) | (Å/min) | Selectivity | (Å) | (Å) |
| Comparative | — | 0 | 0 | 2620 | 15 | 175 | 1986 | 102 |
| Example 1 | | | | | | | | |
| Example 1 | Proline | 1 | 0 | 2411 | 12 | 201 | 1559 | 72 |
| Example 2 | Ribose | 4 | 0 | 2641 | 13 | 203 | 1338 | 69 |
| Example 3 | Glucose | 5 | 0 | 2407 | 12 | 201 | 1248 | 67 |
| Example 4 | Sorbitol | 6 | 0 | 2416 | 10 | 242 | 1127 | 58 |
| Example 5 | N-acetyl-D-glucosamine | 4 | 1 | 2453 | 11 | 223 | 924 | 52 |
| Example 6 | Glucosamine hydrochloride | 4 | 1 | 2221 | 8 | 278 | 774 | 52 |

Referring to Table 1, in the case of the examples, it is found that, even on a low stepped portion of a patterned wafer having a polishing selectivity of 200 or more and a wide width of 2700 μm or more, the amount of dishing occurred is 1600 Å or less and the loss of the nitride film is 75 Å or less. With this, it is found that the polishing selectivity is increased, and the amount of dishing occurred on the oxide film and the loss of the nitride film were reduced, compared with the slurry composition of the comparative example 1, in which the dishing inhibitor is not used. Particularly, it is found that, when the saccharides compound including four or more hydroxy groups (—OH) is included as the dishing inhibitor (Examples 2, 3, and 4), the amount of dishing occurred of 1400 Å or less can be achieved.

In addition, it is found that, when the dishing inhibitor including four or more hydroxy groups (—OH) and an amine group is included (Examples 5 and 6), the effects of the increase in the polishing selectivity, the reduction of the dishing on the oxide film, and the reduction of the loss of the nitride film are further enhanced.

While the example embodiments are described with reference to drawings, it will be apparent to one of ordinary skill in the art that various alterations and modifications in form and details may be made in these example embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

Therefore, other implementations, other example embodiments, and equivalents to the claims are also within the scope of the following claims.

What is claimed is:

1. A polishing slurry composition, comprising:
abrasive particles;
a dispersant;
a pH buffering agent; and
a dishing inhibitor comprising at least one selected from a group consisting of a saccharides compound, an amino acid, and a mixture thereof.

2. The polishing slurry composition of claim 1, wherein
the abrasive particles comprise at least one selected from a group consisting of: a metal oxide; a metal oxide coated with an organic material or inorganic material; and the metal oxide in a colloidal phase, and
the metal oxide comprises at least one selected from a group consisting of silica, ceria, zirconia, alumina, titania, barium titania, germania, mangania, and magnesia.

3. The polishing slurry composition of claim 1, wherein
a primary particle size of the abrasive particles is 5 nanometers (nm) to 150 nm, and
a secondary particle size of the abrasive particles is 30 nm to 300 nm.

4. The polishing slurry composition of claim 1, wherein the abrasive particles are in an amount of 0.1 wt % to 10 wt %.

5. The polishing slurry composition of claim 1, wherein the dispersant comprises at least one selected from a group consisting of picolinic acid, dipicolinic acid, benzoic acid, phenylacetic acid, naphthoic acid, mandelic acid, nicotinic acid, dinicotinic acid, isonicotinic acid, quinolinic acid, anthranilic acid, fusaric acid, phthalic acid, isophthalic acid, terephthalic acid, toluic acid, salicylic acid, nitrobenzoic acid, and pyridinedicarboxylic acid.

6. The polishing slurry composition of claim 1, wherein the dispersant is in an amount of 0.1 wt % to 10 wt %.

7. The polishing slurry composition of claim 1, wherein
the pH buffering agent comprises an amino acid, and
the amino acid comprises at least one selected from a group consisting of histidine, lysine, and arginine.

8. The polishing slurry composition of claim 1, wherein the pH buffering agent is in an amount of 0.01 wt % to 5 wt %.

9. The polishing slurry composition of claim 1, wherein the saccharides compound comprises at least one selected from a group consisting of monosaccharides, polysaccharides, sugar alcohol, and a salt thereof.

10. The polishing slurry composition of claim 1, wherein the saccharides compound comprises four or more hydroxy groups (—OH).

11. The polishing slurry composition of claim 1, wherein the saccharides compound comprises a hydroxy group and an amine group.

12. The polishing slurry composition of claim 1, wherein the dishing inhibitor comprises at least one selected from a group consisting of proline, ribose, glucose, sorbitol, N-acetyl-D-glucosamine, and glucosamine hydrochloride.

13. The polishing slurry composition of claim 1, wherein the dishing inhibitor is in an amount of 0.001 wt % to 1 wt %.

14. The polishing slurry composition of claim 1, further comprising:
a pH adjuster;
wherein the pH adjuster comprises at least one selected from a group consisting of lactic acid, pimelic acid, malic acid, malonic acid, maleic acid, acetic acid, adipic acid, oxalic acid, succinic acid, tartaric acid, citric acid, glutaric acid, glycolic acid, formic acid, fumaric acid, propionic acid, butyric acid, hydroxybutyric acid, aspartic acid, itaconic acid, tricarballylic acid, suberic acid, sebacic acid, stearic acid, pyruvic acid, acetoacetic acid, glyoxylic acid, azelaic acid, a caprylic acid, lauric acid, myristic acid, valeric acid, and palmitic acid.

15. The polishing slurry composition of claim 1, wherein the polishing slurry composition is a positive slurry composition showing a positive charge.

16. The polishing slurry composition of claim 1, wherein the pH of the polishing slurry composition ranges from 4 to 6.

17. The polishing slurry composition of claim 1, wherein
the polishing slurry composition is configured to polish a patterned wafer having a width of 2,000 micrometers (μm) or more, and
the amount of dishing occurred on a low stepped portion of the patterned wafer is 1,600 angstroms (Å) or less.

18. The polishing slurry composition of claim 1, wherein
a polishing speed of an oxide film (SiO₂) is 2,000 Å/min or more, and
a polishing selectivity of the oxide film (SiO₂) to a nitride film (SiN) (the polishing speed of the oxide film (SiO₂)/a polishing speed of the nitride film (SiN)) is 200 or more.
